(19) United States
(12) Patent Application Publication
(10) Pub. No.: US 2025/0329691 A1
(43) Pub. Date: Oct. 23, 2025

(54) SEMICONDUCTOR PACKAGE

(71) Applicant: Samsung Electronics Co., Ltd., Suwon-si (KR)

(72) Inventors: Gyuhyeong KIM, Suwon-si (KR); Yuhyeok KIM, Suwon-si (KR); Jongwan KIM, Suwon-si (KR); Jungsoo JEON, Suwon-si (KR); Taejun JEON, Suwon-si (KR)

(73) Assignee: Samsung Electronics Co., Ltd., Suwon-si (KR)

(21) Appl. No.: 18/907,643

(22) Filed: Oct. 7, 2024

(30) Foreign Application Priority Data
Apr. 23, 2024 (KR) 10-2024-0054200

(51) Int. Cl. H01L 25/065; H01L 23/00; H01L 23/31; H01L 25/00

(52) U.S. Cl. CPC H01L 25/0657; H01L 23/3121; H01L 24/04; H01L 24/29; H01L 24/32; H01L 24/48; H01L 24/73; H01L 25/50; H01L 2224/04042; H01L 2224/29017; H01L 2224/29018; H01L 2224/32145; H01L 2224/32225; H01L 2224/4809; H01L 2224/48147; H01L 2224/48227; H01L 2224/73215; H01L 2224/73265; H01L 2225/06506; H01L 2225/0651; H01L 2225/06562; H01L 2924/35

(57) ABSTRACT

A semiconductor package may include a substrate, a first chip on the substrate, a second chip stacked on and offset from the first chip in a first direction, a third chip stacked on and offset from the second chip in a second direction opposite to the first direction, a first bonding wire connecting the substrate to the first chip, and a second bonding wire connecting the first chip to the third chip. The first chip may include a first chip pad disposed on a top surface of the first chip and spaced apart from the second chip in the second direction. The third chip may include a second chip pad disposed on a bottom surface of the third chip and spaced apart from the second chip in the second direction. The second chip pad may be placed above the first chip pad.

### CROSS-REFERENCE TO RELATED APPLICATIONS

This U.S. non-provisional patent application claims priority under 35 U.S.C. § 119 to Korean Patent Application No. 10-2024-0054200, filed on Apr. 23, 2024, in the Korean Intellectual Property Office, the entire contents of which are hereby incorporated by reference.

### BACKGROUND

The present disclosure relates to semiconductor packages and methods of fabricating the same, and in particular, to semiconductor packages including stacked semiconductor chips and methods of fabricating the same.

With the recent advance in the electronics industry, the demand for high-performance, high-speed, and compact electronic components are increasing. To meet this demand, packaging technologies of mounting a plurality of semiconductor chips in a single package are being developed.

A general stack-type package may have a structure including a plurality of stacked devices. For example, the stack-type package may include semiconductor chips, which are sequentially stacked on a printed circuit board (PCB). Connection pads may be formed on the semiconductor chips. By forming bonding wires connected to the connection pads, the semiconductor chips may be electrically connected to the printed circuit board.

Recently, demand for portable electronic devices has been rapidly increasing in the market, and thus, it is necessary to reduce sizes and weights of electronic components constituting the portable electronic devices. In order to achieve this, it is necessary to develop packaging technologies of reducing a size and a weight of each component and of integrating a plurality of individual components in a single package. In the case of a semiconductor package in which multiple devices are integrated, there is a need to reduce the size of the semiconductor package and improve the structural and electrical characteristics of the semiconductor package.

### SUMMARY

Some example embodiments of the inventive concepts provide semiconductor packages with improved structural stability and a method of fabricating the same.

Some example embodiments of the inventive concepts provide semiconductor packages with a reduced size.

According to an example embodiment of the inventive concepts, a semiconductor package includes a substrate, a first semiconductor chip on the substrate, a second semiconductor chip stacked on the first semiconductor chip, the second semiconductor chip being offset from the first semiconductor chip in a first direction, a third semiconductor chip stacked on the second semiconductor chip, the third semiconductor chip being offset from the second semiconductor chip in a second direction, the second direction being opposite to the first direction, a first bonding wire connecting the substrate to the first semiconductor chip, and a second bonding wire connecting the first semiconductor chip to the third semiconductor chip. The first semiconductor chip may include a first chip pad, the first chip pad being on a top surface of the first semiconductor chip, the first chip pad being spaced apart from the second semiconductor chip in the second direction. The third semiconductor chip may include a second chip pad, the second chip pad being on a bottom surface of the third semiconductor chip, the second chip pad being spaced apart from the second semiconductor chip in the second direction. The second chip pad may be above the first chip pad. The first bonding wire may be extended from a top surface of the substrate to a top surface of the first chip pad, and the second bonding wire may be spaced apart from the second semiconductor chip in the second direction and may be extended from the top surface of the first chip pad to a bottom surface of the second chip pad.

According to an example embodiment of the inventive concepts, a semiconductor package includes a substrate including substrate pads on a top surface of the substrate, an outer connection terminal on a bottom surface of the substrate, a first semiconductor chip on the substrate, the first semiconductor chip including first chip pads, the first chip pads being on a region of a top surface of the first semiconductor chip that is adjacent to a side surface of the first semiconductor chip, a second semiconductor chip stacked on the first semiconductor chip, the second semiconductor chip being offset from the first semiconductor chip in a first direction and horizontally spaced apart from the first chip pads, when viewed in a plan view, a third semiconductor chip stacked on the second semiconductor chip, the third semiconductor chip being offset from the second semiconductor chip in a second direction, the second direction being opposite to the first direction, the third semiconductor chip including second chip pads, the second chip pads being on a bottom surface of the third semiconductor chip and spaced apart from the second semiconductor chip in the second direction, first bonding wires electrically connecting the substrate to the first semiconductor chip, second bonding wires electrically connecting the substrate to the second semiconductor chip, third bonding wires electrically connecting the substrate to the third semiconductor chip, and a mold layer on the substrate, the mold layer covering top and side surfaces of the first to third semiconductor chips, the mold layer enclosing the first to third bonding wires. The third bonding wires may include first sub-wires and second sub-wires, the first sub-wires extending from top surfaces of the substrate pads to top surfaces of the first chip pads in a curved shape, the second sub-wires extending from the top surfaces of the first chip pads to bottom surfaces of the second chip pads in a linear shape.

According to an example embodiment of the inventive concepts, a semiconductor package includes a substrate, a first semiconductor chip and a second semiconductor chip stacked on the substrate to have a stepwise structure in a first direction, the first semiconductor chip including first chip pads, the first chip pads being on a top surface of the first semiconductor chip and spaced apart from the second semiconductor chip in a second direction opposite to the first direction, a third semiconductor chip stacked on the second semiconductor chip, the third semiconductor chip being offset from the second semiconductor chip in the second direction, the third semiconductor chip including second chip pads, the second chip pads being on a bottom surface of the third semiconductor chip and spaced apart from the second semiconductor chip in the second direction, first bonding wires extended from a top surface of the substrate to top surfaces of the first chip pads, and second bonding wires extended from the top surfaces of the first chip pads to bottom surfaces of the second chip pads. The third semiconductor chip may be attached to a top surface of the second semiconductor chip using an adhesive layer covering the bottom surface of the third semiconductor chip. The adhesive layer may expose the bottom surfaces of the second chip pads, and each of the second chip pads may be above a corresponding one of the first chip pads.

### BRIEF DESCRIPTION OF THE DRAWINGS

FIGS. 1 to 5 are sectional views illustrating a semiconductor package according to some example embodiments of the inventive concepts.

FIGS. 6 to 10 are sectional views illustrating a method of fabricating a semiconductor package, according to some example embodiments of the inventive concepts.

### DETAILED DESCRIPTION

Example embodiments of the inventive concepts will now be described more fully with reference to the accompanying drawings, in which some example embodiments are shown.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

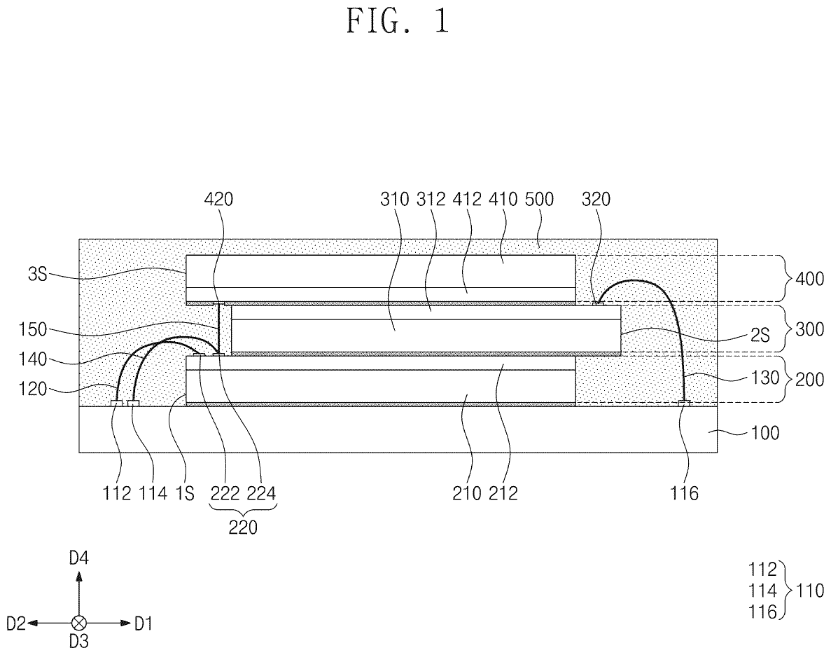

FIG. 1 is a sectional view illustrating a semiconductor package according to an example embodiment of the inventive concepts. Referring to FIG. 1, a substrate 100 may be provided. The substrate 100 may be a printed circuit board (PCB), which has top and bottom surfaces that are opposite to each other. Although not shown, the substrate 100 may include an inner interconnection pattern provided in the substrate 100. For example, the substrate 100 may have a structure, in which insulating patterns and inner interconnection patterns are alternatingly stacked.

FIG. 1 illustrates an example, in which the substrate 100 is the printed circuit board, but the inventive concepts is not limited to this example. In an example embodiment, the substrate 100 may be a redistribution substrate. For example, the substrate 100 may include one substrate interconnection layer or at least two substrate interconnection layers stacked. In the present specification, the substrate interconnection layer may mean an interconnection layer, which includes a patterned structure of a single insulating layer and a patterned structure of a single conductive layer. Each of the substrate interconnection layers may include an insulating pattern and a conductive pattern in the insulating pattern. The conductive pattern of one of the substrate interconnection layers may be electrically connected to the conductive pattern of a neighboring one of the substrate interconnection layers. Upper portions of the conductive patterns, which are included in the uppermost one of the substrate interconnection layers, may correspond to substrate pads 110. Hereinafter, the inventive concepts will be described with reference to the example embodiment of FIG. 1.

The substrate 100 may include the substrate pads 110 disposed on the top surface of in the substrate 100. The substrate pads 110 may be disposed on an outer edge portion of the top surface of the substrate 100. The substrate pads 110 may be electrically connected to the inner interconnection pattern. The substrate pads 110 may be arranged in at least two columns. For example, the substrate pads 110 may be arranged in three columns that are extended in a third direction D3. In each column, the substrate pads 110 may be spaced apart from each other in the third direction D3. The columns may be arranged to be spaced apart from each other in a first direction D1. In the present specification, the first direction D1 may be a direction that is parallel to the top surface of the substrate 100. A second direction D2 may be a direction that is opposite to the first direction D1. In the present specification, the third direction D3 may be a direction that is parallel to the top surface of the substrate 100 and is perpendicular to the first and second directions D1 and D2.

Hereinafter, for convenience in description, the substrate pads 110 of the three columns may be referred to as first column substrate pads 112, second column substrate pads 114, and third column substrate pads 116. The first column substrate pads 112 may mean a group of the substrate pads 110 included in the column that is farthest from a center of the substrate 100 in the second direction D2. The third column substrate pads 116 may mean a group of the substrate pads 110 included in the column that is farthest from the center of the substrate 100 in the first direction D1, and the second column substrate pads 114 may mean a group of the substrate pads 110 included the column between the first and third column substrate pads 112 and 116. For example, the first and second column substrate pads 112 and 114 may be disposed on the top surface of the substrate 100 to be spaced apart from the center of the substrate 100 in the second direction D2, and the third column substrate pads 116 may be disposed on the top surface of the substrate 100 to be spaced apart from the center of the substrate 100 in the first direction D1.

Although not shown, lower substrate pads and outer connection terminals may be provided on a bottom surface of the substrate 100. The lower substrate pads may be additional pads, which are disposed on the bottom surface of the substrate 100 and are connected to the inner interconnection pattern of the substrate 100, or portions of the inner interconnection pattern, which are exposed to the outside of the substrate 100 near the bottom surface of the substrate 100. Each of the outer connection terminals may be disposed on a bottom surface of a corresponding one of the lower substrate pads. The outer connection terminals may include solder balls or solder bumps.

A first semiconductor chip 200 may be provided on the substrate 100. The first semiconductor chip 200 may include a first semiconductor substrate 210 and a first interconnection layer 212 on the first semiconductor substrate 210. The first semiconductor chip 200 may be provided in a face-up manner. For example, a top surface of the first semiconductor chip 200 may be a surface of the first semiconductor chip 200, on which interconnection patterns are formed. The first semiconductor chip 200 may be disposed on a center portion of the substrate 100. When viewed in a plan view, the first semiconductor chip 200 may be horizontally spaced apart from the substrate pads 110, which are disposed on the outer edge portion of the substrate 100. When viewed in a plan view, at least one column of the substrate pads 110 may be disposed at each regions, which are spaced apart from the first semiconductor chip 200 in the first and second directions D1 and D2. For example, the first semiconductor chip 200 may be disposed between the second column substrate pads 114 and the third column substrate pads 116, when viewed in a plan view.

The first semiconductor chip 200 may include the first semiconductor substrate 210. The first semiconductor substrate 210 may include a semiconductor material. The first semiconductor substrate 210 may be a silicon substrate, a silicon-on-insulator (SOI) substrate, a germanium (Ge) substrate, a germanium-on-insulator (GOI) substrate, a silicon-germanium (SiGe) substrate, a group III-V semiconductor substrate, or a substrate including an epitaxial film formed by a selective epitaxial growth (SEG) process. The first semiconductor substrate 210 may be formed of or include at least one of silicon (Si), germanium (Ge), silicon-germanium (SiGe), gallium arsenic (GaAs), indium gallium arsenic (InGaAs), or aluminum gallium arsenic (AlGaAs). The first semiconductor substrate 210 may have an active surface and an inactive surface. In the present specification, the active surface may be defined as a surface of the semiconductor substrate, on which an integrated device or integrated circuits are formed, and the inactive surface may be defined as a surface that is opposite to the active surface. A top surface of the first semiconductor substrate 210 may be the active surface of the first semiconductor substrate 210.

Although not shown, integrated devices or integrated circuits may be formed on the active surface of the first semiconductor substrate 210. The integrated circuit may include a logic circuit or a memory circuit. In other words, the first semiconductor chip 200 may be a logic chip or a memory chip. However, the inventive concepts is not limited to this example, and in an example embodiment, the first semiconductor chip 200 may be a logic chip, a memory chip, or a semiconductor chip including various integrated devices.

The first interconnection layer 212 may be disposed on the active surface of the first semiconductor substrate 210. For example, although not shown, the first interconnection layer 212 may include a first insulating pattern and a first interconnection pattern provided on the active surface of the first semiconductor substrate 210. The first insulating pattern may include an insulating material. For example, the first insulating pattern may be formed of or include at least one of silicon oxide (SiO), silicon nitride (SiN), silicon oxynitride (SiON), silicon carbonitride (SiCN), insulating polymers, or photosensitive insulating materials (PID). The first interconnection pattern may be provided in the first insulating pattern. The first interconnection pattern may be electrically connected to the integrated device or the integrated circuit. The first interconnection pattern may be formed of or include at least one of conductive materials (e.g., copper (Cu) or aluminum (Al)).

The first semiconductor chip 200 may include first pads 220 provided on the active surface of the first semiconductor substrate 210. The first pads 220 may be provided on a region of the top surface of the first semiconductor chip 200, which is adjacent to a first side surface 1S of the first semiconductor chip 200. In the present specification, the first side surface 1S of the first semiconductor chip 200 may be a side surface of the first semiconductor chip 200 that is parallel to the third direction D3 and is spaced apart from a center of the first semiconductor chip 200 in the second direction D2. The first pads 220 may be configured to be spaced apart from each other in the third direction D3. When viewed in a plan view, the first pads 220 may be disposed on the top surface of the first semiconductor chip 200 to form at least two columns. In each column, the first pads 220 may be spaced apart from each other in the third direction D3. The columns may be spaced apart from each other in the second direction D2. Hereinafter, for convenience in description, the first pads 220 that are included in one of the two columns closer to the first side surface 1S may be referred to as first connection pads 222, and the first pads 220 that are included in the other of the two columns may be referred to as second connection pads 224. The first pads 220 may be provided as elements protruding relative to the top surface of the first semiconductor chip 200. However, the inventive concepts is not limited to this example, and in an example embodiment, the first pads 220 may be coplanar with the top surface of the first semiconductor chip 200 and may be exposed to the outside of the first semiconductor chip 200 near the top surface of the first semiconductor chip 200. At least one of the first pads 220 may be electrically connected to the integrated device or the integrated circuits. For example, the first connection pads 222 may be electrically connected to the integrated device or the integrated circuits, and the second connection pads 224 may be electrically disconnected from the integrated device or the integrated circuits.

FIG. 1 illustrates an example, in which the first pads 220 are arranged in at least two columns, but the inventive concepts is not limited to this example. The number of the columns of the first pads 220 may be changed, as desired, and in an example embodiment, the first pads 220 may be arranged in a single column. Here, at least one of the first pads 220 may be electrically connected to the integrated device or the integrated circuits, and others of the first pads 220 may be electrically disconnected from the integrated device or the integrated circuits. The first pads 220 that are not electrically connected to the integrated device or the integrated circuits may be used as dummy pads for connecting the substrate 100 to a third semiconductor chip 400 to be described below.

The first semiconductor chip 200 may be mounted on the substrate 100. For example, the first semiconductor chip 200 may be electrically connected to the substrate 100 through first bonding wires 120. The first bonding wires 120 may be extended from top surfaces of the first column substrate pads 112 to top surfaces of the first connection pads 222, which are provided on the top surface of the first semiconductor chip 200. The first bonding wires 120 may be formed of or include at least one of metallic materials (e.g., gold (Au)). The substrate 100 may be electrically connected to the integrated circuits of the first semiconductor chip 200 through the first bonding wires 120 and the first connection pads 222.

The first semiconductor chip 200 may be attached to the substrate 100 using a first adhesive layer. Throughout the drawings, shaded areas between the various semiconductor chips and between the substrate and the lowermost semiconductor chip refer to various adhesive layer therebetween, although specific reference numerals are not specifically assigned thereto. The first adhesive layer may include a conductive film (e.g., a die attach film (DAF)) or a non-conductive film (NCF). The first adhesive layer may cover a bottom surface of the first semiconductor chip 200 and may fill a space between the substrate 100 and the first semiconductor chip 200.

A second semiconductor chip 300 may be provided on the top surface of the first semiconductor chip 200. The second semiconductor chip 300 may include a second semiconductor substrate 310 and a second interconnection layer 312 on the second semiconductor substrate 310. The second semiconductor chip 300 may be provided in a face-up manner. For example, a top surface of the second semiconductor chip 300 may be a surface of the second semiconductor chip 300, on which interconnection patterns are formed. The second semiconductor chip 300 may be stacked on the first semiconductor chip 200 and may be offset from the first semiconductor chip 200 in the first direction D1. In other words, the first semiconductor chip 200 and the second semiconductor chip 300 may be stacked on the substrate 100 to form a stepwise structure in the first direction D1. At least a portion of the second semiconductor chip 300 may vertically overlap at least a portion of the first semiconductor chip 200. The remaining portion of the second semiconductor chip 300 may protrude relative to a side surface of the first semiconductor chip 200, which is opposite to the first side surface 1S. When viewed in a plan view, the first pads 220 may be horizontally spaced apart from the second semiconductor chip 300. The first pads 220 may be disposed on the top surface of the first semiconductor chip 200 and may be spaced apart from the second semiconductor chip 300 in the second direction D2.

The second semiconductor chip 300 may include the second semiconductor substrate 310. The second semiconductor substrate 310 may include a semiconductor material. The second semiconductor substrate 310 may be a silicon substrate, a silicon-on-insulator (SOI) substrate, a germanium (Ge) substrate, a germanium-on-insulator (GOI) substrate, a silicon-germanium (SiGe) substrate, a group III-V semiconductor substrate, or a substrate including an epitaxial film formed by a selective epitaxial growth (SEG) process. The second semiconductor substrate 310 may be formed of or include at least one of silicon (Si), germanium (Ge), silicon-germanium (SiGe), gallium arsenic (GaAs), indium gallium arsenic (InGaAs), or aluminum gallium arsenic (AlGaAs). Although not shown, integrated devices or integrated circuits may be formed on an active surface of the second semiconductor substrate 310. A top surface of the second semiconductor substrate 310 may be the active surface of the second semiconductor substrate 310. The integrated circuit may include a logic circuit or a memory circuit. In other words, the second semiconductor chip 300 may be a logic chip or a memory chip. However, the inventive concepts is not limited to this example, and in an example embodiment, the second semiconductor chip 300 may be a logic chip, a memory chip, or a semiconductor chip including various integrated devices.

The second interconnection layer 312 may be disposed on the active surface of the second semiconductor substrate 310. For example, although not shown, the second interconnection layer 312 may include a second insulating pattern and a second interconnection pattern provided on the active surface of the second semiconductor substrate 310. The second insulating pattern may include an insulating material. For example, the second insulating pattern may be formed of or include at least one of silicon oxide (SiO), silicon nitride (SiN), silicon oxynitride (SiON), silicon carbonitride (SiCN), insulating polymers, or photosensitive insulating materials (PID). The second interconnection pattern may be provided in the second insulating pattern. The second interconnection pattern may be electrically connected to the integrated device or the integrated circuit. The second interconnection pattern may be formed of or include at least one of conductive materials (e.g., copper (Cu) or aluminum (Al)).

The second semiconductor chip 300 may be attached to the first semiconductor chip 200 using a second adhesive layer. The second adhesive layer may include a conductive film (e.g., a die attach film (DAF)) or a non-conductive film (NCF). The second adhesive layer may cover a bottom surface of the second semiconductor chip 300. FIG. 1 illustrates an example, in which the bottom surface of the second semiconductor chip 300 is fully covered with the second adhesive layer, but the inventive concepts is not limited to this example. The second adhesive layer may be provided only between the top surface of the first semiconductor chip 200 and the bottom surface of the second semiconductor chip 300. For example, the second adhesive layer may be locally interposed in a local region between the first semiconductor chip 200 and the second semiconductor chip 300, which vertically overlap each other, and may fill a space between the first semiconductor chip 200 and the second semiconductor chip 300.

The second semiconductor chip 300 may include second pads 320 provided on the active surface of the second semiconductor substrate 310. The second pads 320 may be pads that are connected to the integrated device or the integrated circuits. The second pads 320 may be disposed on the top surface of the second semiconductor chip 300 and may be spaced apart from the first semiconductor chip 200 in the first direction D1. The second pads 320 may be spaced apart from each other in the third direction D3 to form a single column. The second pads 320 may be provided as elements protruding relative to the second semiconductor chip 300. However, the inventive concepts is not limited to this example, and in an example embodiment, the second pads 320 may be coplanar with the top surface of the second semiconductor chip 300 and may be exposed to the outside of the second semiconductor chip 300 near the top surface of the second semiconductor chip 300.

The second semiconductor chip 300 may be electrically connected to the substrate 100. For example, the second semiconductor chip 300 may be electrically connected to the substrate 100 through second bonding wires 130. The second bonding wires 130 may be extended from top surfaces of the third column substrate pads 116 to the top surfaces of the second pads 320 of the second semiconductor chip 300. The third column substrate pads 116 may be disposed to be spaced apart from a second side surface 2S in the first direction D1, when viewed in a plan view. The second side surface 2S may mean one of the side surfaces, which are parallel to the third direction D3 and is farthest from the first side surface 1S of the first semiconductor chip 200 in the first direction D1. The second bonding wires 130 may be spaced apart from the second side surface 2S of the second semiconductor chip 300 in the first direction D1. The second bonding wires 130 may have a loop-shaped portion that protrude above relative to the top surface of the second semiconductor chip 300. The second bonding wires 130 may be formed of or include at least one of metallic materials (e.g., gold (Au)). The substrate 100 may be electrically connected to the integrated circuits of the second semiconductor chip 300 through the second bonding wires 130 and the second pads 320.

The third semiconductor chip 400 may be provided on the top surface of the second semiconductor chip 300. The third semiconductor chip 400 may include a third semiconductor substrate 410 and a third interconnection layer 412 on the third semiconductor substrate 410. The third semiconductor chip 400 may be provided in a face-down manner. For example, a bottom surface of the third semiconductor chip 400 may be an active surface of the third semiconductor chip 400, on which interconnection patterns are formed. The third semiconductor chip 400 may be stacked on the second semiconductor chip 300 and may be offset from the second semiconductor chip 300 in the second direction D2. At least a portion of the third semiconductor chip 400 may vertically overlap at least a portion of the second semiconductor chip 300. The remaining portion of the third semiconductor chip 400 may protrude relative to a side surface of the second semiconductor chip 300, which is opposite to the second side surface 2S. For example, a portion of the bottom surface of the third semiconductor chip 400, which is adjacent to a third side surface 3S of the third semiconductor chip 400, may not overlap the second semiconductor chip 300. The third side surface 3S may be a side surface, which is one of side surfaces parallel to the third direction D3 and is farthest from the second side surface 2S of the second semiconductor chip 300 in the second direction D2. The third semiconductor chip 400 may vertically overlap the first semiconductor chip 200. For example, the first side surface 1S and the third side surface 3S may be coplanar with each other, but the inventive concepts is not limited to this example.

The third semiconductor chip 400 may include the third semiconductor substrate 410. The third semiconductor substrate 410 may include a semiconductor material. The third semiconductor substrate 410 may be a silicon substrate, a silicon-on-insulator (SOI) substrate, a germanium (Ge) substrate, a germanium-on-insulator (GOI) substrate, a silicon-germanium (SiGe) substrate, a group III-V semiconductor substrate, or a substrate including an epitaxial film formed by a selective epitaxial growth (SEG) process. The third semiconductor substrate 410 may be formed of or include at least one of silicon (Si), germanium (Ge), silicon-germanium (SiGe), gallium arsenic (GaAs), indium gallium arsenic (InGaAs), or aluminum gallium arsenic (AlGaAs). Although not shown, integrated devices or integrated circuits may be formed on an active surface of the third semiconductor substrate 410. A bottom surface of the third semiconductor substrate 410 may be the active surface of the third semiconductor substrate 410. The integrated circuit may include a logic circuit or a memory circuit. In other words, the third semiconductor chip 400 may be a logic chip or a memory chip. However, the inventive concepts is not limited to this example, and in an example embodiment, the third semiconductor chip 400 may be a logic chip, a memory chip, or a semiconductor chip including various integrated devices.

The third interconnection layer 412 may be disposed on the bottom surface of the third semiconductor substrate 410. For example, although not shown, the third interconnection layer 412 may include a third insulating pattern and a third interconnection pattern provided on the active surface of the third semiconductor substrate 410. The third insulating pattern may include an insulating material. For example, the third insulating pattern may be formed of or include at least one of silicon oxide (SiO), silicon nitride (SiN), silicon oxynitride (SiON), silicon carbonitride (SiCN), insulating polymers, or photosensitive insulating materials (PID). The third interconnection pattern may be provided in the third insulating pattern. The third interconnection pattern may be electrically connected to the integrated device or the integrated circuit. The third interconnection pattern may be formed of or include at least one of conductive materials (e.g., copper (Cu) or aluminum (Al)).

The third semiconductor chip 400 may include third pads 420, which are disposed on the bottom surface of the third semiconductor chip 400 and are spaced apart from the second semiconductor chip 300 in the second direction D2. The third pads 420 may be connected to the integrated device or the integrated circuits of the third semiconductor chip 400. The third pads 420 may be spaced apart from each other in the third direction D3 to form a single column. The third pads 420 may be provided as elements protruding relative to the bottom surface of the third semiconductor chip 400. However, the inventive concepts is not limited to this example, and in an example embodiment, the third pads 420 may be coplanar with the bottom surface of the third semiconductor chip 400 and may be exposed to the outside of the third semiconductor chip 400 near the top surface of the third semiconductor chip 400. The third pads 420 may be placed above the second connection pads 224. When viewed in a plan view, at least a portion of the third pads 420 may vertically overlap at least a portion of the second connection pads 224. For example, each of the third pads 420 may face a corresponding one of the second connection pads 224.

The third semiconductor chip 400 may be attached to the second semiconductor chip 300 using a third adhesive layer. The third adhesive layer may include a conductive film (e.g., a die attach film (DAF)) or a non-conductive film (NCF). The third adhesive layer may cover the bottom surface of the third semiconductor chip 400. FIG. 1 illustrates an example, in which the bottom surface of the third semiconductor chip 400 is fully covered with the third adhesive layer, but the inventive concepts is not limited to this example. The third adhesive layer may be provided only between the top surface of the second semiconductor chip 300 and the bottom surface of the third semiconductor chip 400. In other words, the third adhesive layer may be locally interposed in a local region between the second semiconductor chip 300 and the third semiconductor chip 400, which vertically overlap each other, and may fill a space between the second semiconductor chip 300 and the third semiconductor chip 400. Hereinafter, the inventive concepts will be described with reference to the example embodiment of FIG. 1.

The third adhesive layer may include penetration holes. Each of the penetration holes may be placed on a bottom surface of each of the third pads 420. The penetration holes may vertically penetrate the third adhesive layer. The penetration hole may expose the bottom surfaces of the third pads 420. The penetration hole may define an opening to accommodate the third pads 420. In other words, the third adhesive layer may cover the bottom surface of the third semiconductor chip 400 and may enclose side surfaces of the third pads 420.

The third semiconductor chip 400 may be electrically connected to the substrate 100. For example, the third semiconductor chip 400 may be electrically connected to the substrate 100 through third bonding wires 140 and fourth bonding wires 150. The third bonding wires 140 may connect the substrate 100 to the first semiconductor chip 200. The third bonding wires 140 may be extended from top surfaces of the second column substrate pads 114 to top surfaces of the second connection pads 224, which are provided on the top surface of the first semiconductor chip 200. The fourth bonding wires 150 may connect the first semiconductor chip 200 to the third semiconductor chip 400. The fourth bonding wires 150 may be extended from the second connection pads 224 to the third pads 420 of the third semiconductor chip 400. The fourth bonding wires 150 may be extended from the top surfaces of the second connection pads 224 in a fourth direction D4 perpendicular to the top surface of the first semiconductor chip 200 and may be coupled to bottom surface of the third pads 420, respectively. The second column substrate pads 114 may not be connected to the integrated device or integrated circuits of the first semiconductor chip 200 and may be used to electrically connect the substrate 100 to the third semiconductor chip 400. Although not shown, if desired, the first semiconductor chip 200 may include additional interconnection patterns, which are used for redistribution between the substrate 100 and the third semiconductor chip 400. Here, the second connection pads 224 may be electrically connected to the additional interconnection patterns. However, the inventive concepts is not limited to this example. The third pads 420 may be placed above the second connection pads 224. At least a portion of each of the second connection pads 224 and at least a portion of a corresponding one of the third pads 420 may vertically overlap each other. The fourth bonding wires 150 may be spaced apart from a side surface of the second semiconductor chip 300, which is opposite to the second side surface 2S, in the second direction D2. The fourth bonding wires 150 may be provided to overlap the third semiconductor chip 400, when viewed in a plan view. The fourth bonding wires 150 may be a linear shape. However, the inventive concepts is not limited to this example, and in an example embodiment, the fourth bonding wires 150 may have a curved shape. The fourth bonding wires 150 may be formed of or include at least one of metallic materials (e.g., gold (Au)).

A mold layer 500 may be provided on the top surface of the substrate 100 to cover the first to third semiconductor chips 200, 300, and 400. The mold layer 500 may cover side and top surfaces of the first to third semiconductor chips 200, 300, and 400. However, the inventive concepts is not limited to this example. A top surface of the third semiconductor chip 400 may be exposed to the outside of the mold layer 500 near a top surface of the mold layer 500. The top surface of the mold layer 500 and the top surface of the third semiconductor chip 400 may be coplanar with each other. The mold layer 500 may fill a space between the first semiconductor chip 200 and the third semiconductor chip 400 and between the substrate 100 and the second semiconductor chip 300. The mold layer 500 may enclose the first to fourth bonding wires 120, 130, 140, and 150. For example, the mold layer 500 may fill a space between the second connection pads 224 and the third pads 420 and may enclose the fourth bonding wires 150.

Because the third pads 420 are provided on the bottom surface of the third semiconductor chip 400 and the fourth bonding wires 150 on the bottom surface of the third semiconductor chip 400 are used to connect the second connection pads 224 to the third pads 420, the fourth bonding wire 150 may not protrude relative to the third side surface 3S of the third semiconductor chip 400 and the top surface of the third semiconductor chip 400. Thus, it may be possible to omit an additional mold layer, which is needed to enclose a loop-shape portion of a bonding wire protruding relative to the top surface of the third semiconductor chip 400, and to reduce the size of the semiconductor package.

In addition, because the fourth bonding wire 150 is used to vertically connect the top surface of the first semiconductor chip 200 to the bottom surface of the third semiconductor chip 400, it may be used to support a portion of the bottom surface of the third semiconductor chip 400 that does not overlap the second semiconductor chip 300. Thus, a semiconductor package with improved structural stability may be provided.

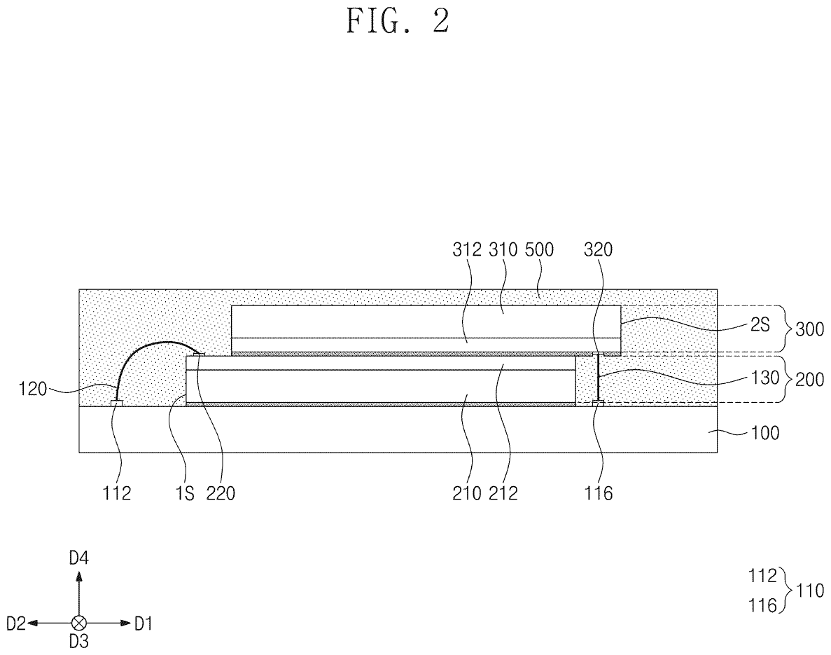

FIG. 2 is a sectional view illustrating a semiconductor package according to an example embodiment of the inventive concepts. Referring to FIG. 2, the substrate 100 may be provided. The substrate 100 may be configured to have the same or substantially similar features as that in the example embodiment of FIG. 1. However, unlike the structure of FIG. 1, the second column substrate pads 114 may not be provided on the top surface of the substrate 100. For example, the substrate pads 110 may be arranged in two columns that are extended in the third direction D3. In each column, the substrate pads 110 may be spaced apart from each other in the third direction D3. The columns may be arranged to be spaced apart from each other in a first direction D1. The substrate pads 110 in one of the two columns may be referred to as first column substrate pads 112, and the substrate pads 110 in the other column may be referred to as third column substrate pads 116. The first column substrate pads 112 may mean a group of the substrate pads 110 included in the column that is spaced apart from the center of the substrate 100 in the second direction D2, and the third column substrate pads 116 may mean a group of the substrate pads 110 included in the column that is spaced apart from the center of the substrate 100 in the first direction D1.

The first semiconductor chip 200 may be provided on the substrate 100 in a face-up manner. The first semiconductor chip 200 may be configured to have the same or substantially similar features as that in the example embodiment of FIG. 1. However, unlike the structure of FIG. 1, the first pads 220 of the first semiconductor chip 200 may be arranged in a single column. The first pads 220 in the single column may be disposed to be spaced apart from each other in the third direction D3. The first pads 220 may be electrically connected to an integrated device or an integrated circuit of the first semiconductor chip 200. The first semiconductor chip 200 may be disposed on the center portion of the substrate 100. When viewed in a plan view, at least one column of the substrate pads 110 may be disposed at a corresponding region, which is spaced apart from the first semiconductor chip 200 in one of the first and second directions D1 and D2. For example, the first semiconductor chip 200 may be disposed between the first and third column substrate pads 112 and 116, when viewed in a plan view.

The second semiconductor chip 300 may be provided on the first semiconductor chip 200. The second semiconductor chip 300 may be configured to have the same or substantially similar features as that in the example embodiment of FIG. 1. However, unlike the example embodiment of FIG. 1, the second semiconductor chip 300 may be provided on the first semiconductor chip 200 in a face-down manner. Although not shown, integrated devices or integrated circuits may be formed on a bottom surface of the second semiconductor substrate 310. The bottom surface of the second semiconductor substrate 310 may be an active surface of the second semiconductor substrate 310. The second interconnection layer 312 may be provided on the bottom surface of the second semiconductor substrate 310. Although not shown, the second interconnection layer 312 may include a second insulating pattern and a second interconnection pattern, which are provided on the bottom surface of the second semiconductor substrate 310, and the second interconnection pattern may be electrically connected to the integrated device or integrated circuits.

The second semiconductor chip 300 may include the second pads 320 provided on the bottom surface of the second semiconductor chip 300. The second pads 320 may be pads that are connected to the integrated device or the integrated circuits. The second pads 320 may be provided on a region of the bottom surface of the second semiconductor chip 300, which is adjacent to the second side surface 2S of the second semiconductor chip 300. The second pads 320 may be spaced apart from each other in the third direction D3 to form a single column. The second pads 320 may be placed above the third column substrate pads 116. At least a portion of each of the second pads 320 may vertically overlap at least a portion of each of the third column substrate pads 116. The second pads 320 may be provided as elements protruding relative to the second semiconductor chip 300. However, the inventive concepts is not limited to this example, and in an example embodiment, the second pads 320 may be coplanar with the bottom surface of the second semiconductor chip 300 and may be exposed to the outside of the second semiconductor chip 300 near the bottom surface of the second semiconductor chip 300.

A second adhesive layer may cover the bottom surface of the second semiconductor chip 300. The second adhesive layer may include penetration holes. Each of the penetration holes may be placed on a bottom surface of each of the second pads 320. The penetration holes may vertically penetrate the second adhesive layer. The bottom surfaces of the second pads 320 may be exposed through the penetration holes. In other words, the second adhesive layer may cover the bottom surface of the second semiconductor chip 300 and enclose side surfaces of the second pads 320.

The second semiconductor chip 300 may be electrically connected to the substrate 100. For example, the second semiconductor chip 300 may be electrically connected to the substrate 100 through the second bonding wires 130. The second bonding wires 130 may be extended from the top surfaces of the third column substrate pads 116 to the bottom surfaces of the second pads 320 of the second semiconductor chip 300. The substrate 100 may be electrically connected to the integrated circuits of the second semiconductor chip 300 through the second bonding wires 130 and the second pads 320. Unlike the second bonding wires 130 described with reference to FIG. 1, the second bonding wires 130 may not protrude relative to the second side surface 2S of the second semiconductor chip 300 in the first direction D1. The second bonding wires 130 may have a linear shape. For example, the second bonding wires 130 may have a linear shape parallel to the fourth direction D4. However, the inventive concepts is not limited to this example, and in an example embodiment, the second bonding wires 130 may have a curved shape.

The mold layer 500 may be provided on the top surface of the substrate 100 to cover the first and second semiconductor chips 200 and 300. The mold layer 500 may cover side and top surfaces of the first and second semiconductor chips 200 and 300. However, the inventive concepts is not limited to this example. The top surface of the second semiconductor chip 300 may be exposed to the outside of the mold layer 500 near the top surface of the mold layer 500. The mold layer 500 may fill a space between the substrate 100 and the second semiconductor chip 300. The mold layer 500 may enclose the first and second bonding wires 120 and 130.

FIG. 1 illustrates an example, in which the second semiconductor chip 300 is mounted in a face-up manner, but the inventive concepts is not limited to this example.

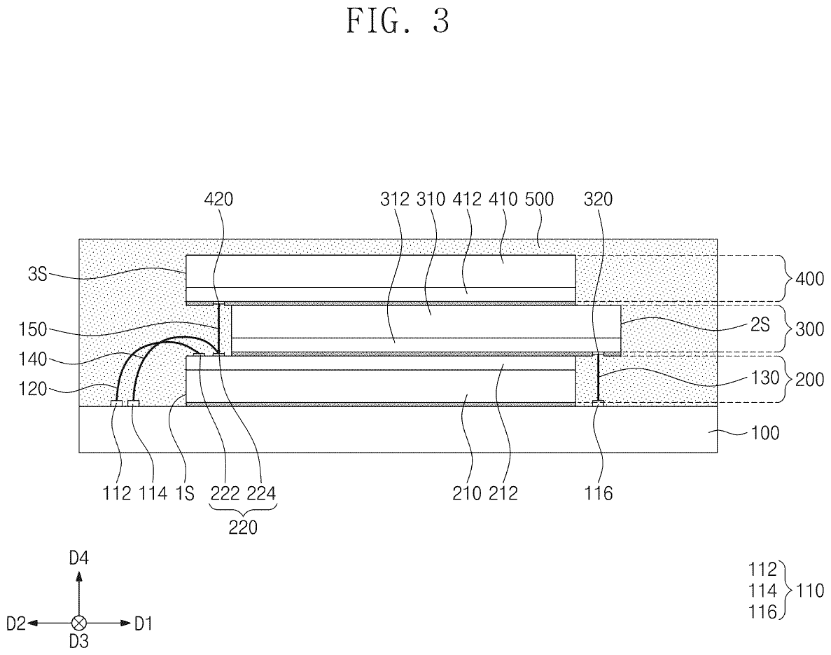

FIG. 3 is a sectional view illustrating a semiconductor package according to an example embodiment of the inventive concepts. Similar to the structure of FIG. 1, the first to third semiconductor chips 200, 300, and 400 may be stacked on the top surface of the substrate 100 to be offset from each other. For example, the second semiconductor chip 300 may be stacked on the first semiconductor chip 200 and may be offset from the first semiconductor chip 200 in the first direction D1, and the third semiconductor chip 400 may be stacked on the second semiconductor chip 300 and may be offset from the second semiconductor chip 300 in the second direction D2. However, unlike the example embodiment of FIG. 1, the second semiconductor chip 300 may be provided on the first semiconductor chip 200 in a face-down manner. The second semiconductor chip 300 may be placed in the same or substantially similar manner as in FIG. 2. For example, the bottom surface of the second semiconductor substrate 310 may be the active surface. The second semiconductor chip 300 may include the second pads 320 provided on the bottom surface of the second semiconductor chip 300. The second pads 320 may be placed above the third column substrate pads 116. At least a portion of each of the second pads 320 may vertically overlap at least a portion of a corresponding one of the third column substrate pads 116. A second adhesive layer may cover the bottom surface of the second semiconductor chip 300. The second adhesive layer may include penetration holes. Each of the penetration holes may be placed on a bottom surface of each of the second pads 320. The penetration holes may vertically penetrate the second adhesive layer. The bottom surfaces of the second pads 320 may be exposed through the penetration holes.

The second semiconductor chip 300 may be mounted on the substrate 100 and electrically connected to the substrate through the second bonding wires 130. The second bonding wires 130 may be extended from top surfaces of the third column substrate pads 116 to the bottom surfaces of the second pads 320 of the second semiconductor chip 300. For example, the second semiconductor chip 300 may be electrically connected to the substrate 100 through the second bonding wires 130, which are extended in the fourth direction D4 and have a linear shape.

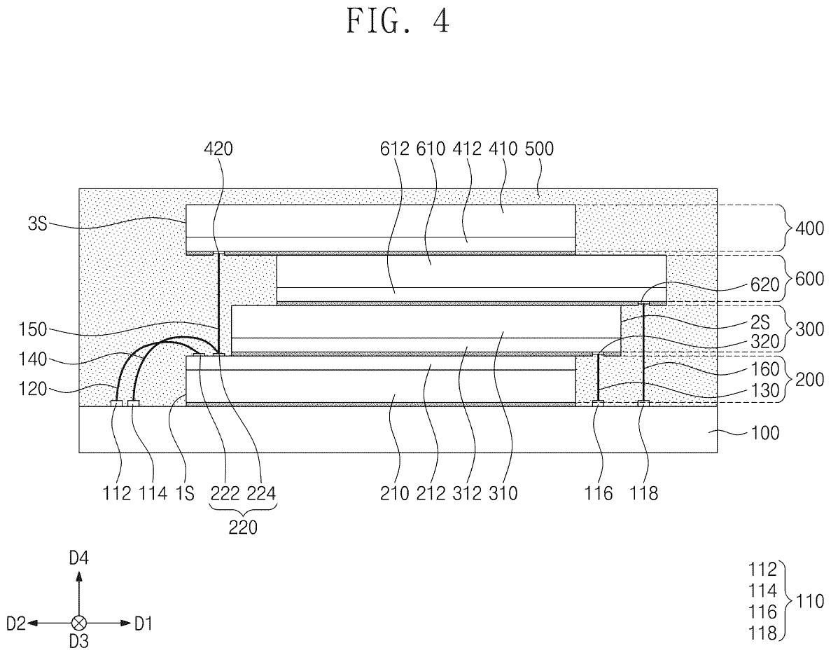

FIG. 4 is a sectional view illustrating a semiconductor package according to an example embodiment of the inventive concepts. Referring to FIG. 4, the substrate 100 may be provided. The substrate 100 may have the same or substantially similar features as that in the example embodiment of FIG. 1. However, unlike the example embodiment of FIG. 2, the substrate pads 110 may further include fourth column substrate pads 118. For example, the substrate pads 110 may be arranged in four columns extended in the third direction D3. The fourth column substrate pads 118 may mean a group of the substrate pads 110 included in the column that is spaced apart from the third column substrate pads 116 in the first direction D1. The fourth column substrate pads 118 may mean a group of the substrate pads 110 included in the column that is farthest from the center of the substrate 100 in the first direction D1. The fourth column substrate pads 118 may be electrically connected to the inner interconnection pattern of the substrate 100. The fourth column substrate pads 118 may be arranged in a single column extended in the third direction D3, and the fourth column substrate pads 118 in the single column may be spaced apart from each other in the third direction D3.

The first to third semiconductor chips 200, 300, and 400 may be stacked on the substrate 100. Here, the first to third semiconductor chips 200, 300, and 400 may have the same or substantially similar features as those in the example embodiment of FIG. 3. However, unlike the example embodiment of FIG. 3, a fourth semiconductor chip 600 may be further provided on the substrate 100. The fourth semiconductor chip 600 may be provided between the second semiconductor chip 300 and the third semiconductor chip 400. The fourth semiconductor chip 600 may be stacked on the second semiconductor chip 300 and may be offset from the second semiconductor chip 300 in the first direction D1. At least a portion of the fourth semiconductor chip 600 may vertically overlap at least a portion of the second semiconductor chip 300. The remaining portion of the fourth semiconductor chip 600 may protrude relative to the second side surface 2S of the second semiconductor chip 300. In other words, the first semiconductor chip 200, the second semiconductor chip 300, and the fourth semiconductor chip 600 may be stacked on the top surface of the substrate 100 to form a stepwise structure in the first direction D1.

The fourth semiconductor chip 600 may include a fourth semiconductor substrate 610 and a fourth interconnection layer 612 on the fourth semiconductor substrate 610. The fourth semiconductor chip 600 may be provided in a face-down manner. For example, a bottom surface of the fourth semiconductor chip 600 may be an active surface of the fourth semiconductor chip 600, on which interconnection patterns are formed. The fourth semiconductor substrate 610 may include a semiconductor material. The fourth semiconductor substrate 610 may be a silicon substrate, a silicon-on-insulator (SOI) substrate, a germanium (Ge) substrate, a germanium-on-insulator (GOI) substrate, a silicon-germanium (SiGe) substrate, a group III-V semiconductor substrate, or a substrate including an epitaxial film formed by a selective epitaxial growth (SEG) process. The fourth semiconductor substrate 610 may be formed of or include at least one of silicon (Si), germanium (Ge), silicon-germanium (SiGe), gallium arsenic (GaAs), indium gallium arsenic (InGaAs), or aluminum gallium arsenic (AlGaAs). Although not shown, integrated devices or integrated circuits may be provided on the active surface of the fourth semiconductor substrate 610. A bottom surface of the fourth semiconductor substrate 610 may be the active surface of the fourth semiconductor substrate 610. The integrated circuit may include a logic circuit or a memory circuit. In other words, the fourth semiconductor chip 600 may be a logic chip or memory chip. However, the inventive concepts is not limited to this example, and in an example embodiment, the fourth semiconductor chip 600 may be a logic chip, a memory chip, or a semiconductor chip including various integrated devices.

The fourth interconnection layer 612 may be disposed on the active surface of the fourth semiconductor substrate 610. For example, although not shown, the fourth interconnection layer 612 may include a fourth insulating pattern and a fourth interconnection pattern that are provided on the active surface of the fourth semiconductor substrate 610. The fourth insulating pattern may include an insulating material. For example, the fourth insulating pattern may be formed of or include at least one of silicon oxide (SiO), silicon nitride (SiN), silicon oxynitride (SiON), silicon carbonitride (SiCN), insulating polymers, or photosensitive insulating materials (PID). The fourth interconnection pattern may be provided in the fourth insulating pattern. The fourth interconnection pattern may be electrically connected to the integrated device or the integrated circuit. The fourth interconnection pattern may be formed of or include at least one of conductive materials (e.g., copper (Cu) or aluminum (Al)).

The fourth semiconductor chip 600 may include fourth pads 620, which are provided on the bottom surface of the fourth semiconductor chip 600. The fourth pads 620 may be a pad that is connected to the integrated device or the integrated circuits. The fourth pads 620 may be disposed on the bottom surface of the fourth semiconductor chip 600 and may be spaced apart from the second side surface 2S of the second semiconductor chip 300 in the first direction D1. In an example embodiment, the fourth pads 620 may be spaced apart from each other in the third direction D3 to form a single column. The fourth pads 620 may be provided as elements protruding relative to the fourth semiconductor chip 600. However, the inventive concepts is not limited to this example, and in an example embodiment, the fourth pads 620 may be coplanar with the bottom surface of the fourth semiconductor chip 600 and may be exposed to the outside of the fourth semiconductor chip 600 near the bottom surface of the fourth semiconductor chip 600. The fourth pads 620 may be placed above the fourth column substrate pads 118. When viewed in a plan view, at least a portion of each of the fourth column substrate pads 118 may vertically overlap a corresponding one of the fourth pads 620.

The fourth semiconductor chip 600 may be attached to the second semiconductor chip 300 using a fourth adhesive layer. The fourth adhesive layer may include a conductive film (e.g., die attach film (DAF)) or a non-conductive film (NCF). The fourth adhesive layer may cover the bottom surface of the fourth semiconductor chip 600. FIG. 3 illustrates an example, in which the bottom surface of the fourth semiconductor chip 600 is fully covered with the fourth adhesive layer, but the inventive concepts is not limited to this example. The fourth adhesive layer may be provided only between the top surface of the second semiconductor chip 300 and the bottom surface of the fourth semiconductor chip 600. For example, the fourth adhesive layer may be locally interposed in a local region between the second semiconductor chip 300 and the fourth semiconductor chip 600 that vertically overlap each other, and may fill a space between the second semiconductor chip 300 and the fourth semiconductor chip 600. The fourth adhesive layer may include penetration holes. Each of the penetration holes may be placed on a bottom surface of each of the fourth pads 620. The penetration holes may vertically penetrate the fourth adhesive layer. The bottom surfaces of the fourth pads 620 may be exposed through the penetration holes. In other words, the fourth adhesive layer may cover the bottom surface of the fourth semiconductor chip 600 and to enclose the fourth pads 620.

The third semiconductor chip 400 may be provided on a top surface of the fourth semiconductor chip 600. The third semiconductor chip 400 may be stacked on the fourth semiconductor chip 600 and may be offset from the fourth semiconductor chip 600 in the second direction D2. At least a portion of the third semiconductor chip 400 may vertically overlap at least a portion of the fourth semiconductor chip 600. A portion of the bottom surface of the third semiconductor chip 400, which is adjacent to the third side surface 3S of the third semiconductor chip 400, may not overlap the fourth semiconductor chip 600. On the bottom surface of the third semiconductor chip 400, the third pads 420 of the third semiconductor chip 400 may be spaced apart from the fourth semiconductor chip 600 in the second direction D2.

The fourth semiconductor chip 600 may be electrically connected to the substrate 100. For example, the fourth semiconductor chip 600 may be electrically connected to the substrate 100 through fifth bonding wires 160. The fifth bonding wires 160 may be extended from the top surfaces of the fourth column substrate pads 118 to the bottom surfaces of the fourth pads 620 of the fourth semiconductor chip 600. The fourth column substrate pads 118 may be spaced apart from the second side surface 2S in the first direction D1, when viewed in a plan view. The fifth bonding wires 160 may have a linear shape. However, the inventive concepts is not limited to this example, and in an example embodiment, the fifth bonding wires 160 may have a curved shape. The fifth bonding wires 160 may be formed of or include at least one of metallic materials (e.g., gold (Au)). The substrate 100 may be electrically connected to the integrated circuits of the fourth semiconductor chip 600 through the fifth bonding wires 160 and the fourth pads 620.

FIG. 4 illustrates an example, in which one semiconductor chip is stacked between the second semiconductor chip 300 and the third semiconductor chip 400, but the inventive concepts is not limited to this example. A plurality of semiconductor chips may be provided between the second semiconductor chip 300 and the third semiconductor chip 400 and may be referred to as interposed semiconductor chips. The semiconductor chips may be stacked on the top surface of the second semiconductor chip 300 and may be offset from the second semiconductor chip 300 in the first direction D1. In other words, the first semiconductor chip 200, the second semiconductor chip 300, and the interposed semiconductor chips may be stacked on the substrate 100 to form a stepwise structure in the first direction D1. The third semiconductor chip 400 may be stacked on the uppermost one of the interposed semiconductor chips and may be offset from the uppermost semiconductor chip in the second direction D2. The third pads 420 of the third semiconductor chip 400 may be disposed on the bottom surface of the third semiconductor chip 400 and may be spaced apart from the uppermost semiconductor chip in the second direction D2.

The interposed semiconductor chips may be provided in a face-down manner and may be attached using an adhesive layer provided on the bottom surface of each of the interposed semiconductor chips. The interposed semiconductor chips may include chip pads provided on the bottom surface of each of the interposed semiconductor chips. The chip pads may be placed on the bottom surface of each of the interposed semiconductor chips and may be spaced apart from an underlying semiconductor chip in the first direction D1. Here, the substrate 100 may further include substrate pads, which are placed above the chip pads, respectively. The semiconductor chips may be electrically connected to the substrate 100 through bonding wires. The bonding wire may be extended from the bottom surface of each of the chip pads to a top surface of a corresponding one of the substrate pads. The bonding wires may have a linear shape. However, the inventive concepts is not limited to this example, and in an example embodiment, the bonding wires may have a curved shape.

FIG. 4 illustrates an example, in which the fourth semiconductor chip 600 is provided on the second semiconductor chip 300 in a face-down manner, but the inventive concepts is not limited to this example. For example, The fourth semiconductor chip 600 may be stacked on the second semiconductor chip 300 in a face-up manner. Here, a top surface of the fourth semiconductor substrate 610 may be an active surface. The fourth interconnection layer 612 may be provided on the active surface of the fourth semiconductor substrate 610. The fourth pads 620 may be provided on the active surface of the fourth semiconductor substrate 610. The fourth pads 620 may be provided on a region of the top surface of the fourth semiconductor chip 600 that is adjacent to the second side surface 2S of the second semiconductor chip 300. The fourth pads 620 may be provided on the top surface of the fourth semiconductor chip 600 and may be spaced apart from the third semiconductor chip 400 in the first direction D1. The fifth bonding wires 160 may electrically connect the fourth column substrate pads 118 to the fourth pads 620. Because the fourth pads 620 are provided on the top surface of the fourth semiconductor chip 600, the fifth bonding wires 160 may protrude from the fourth semiconductor chip 600 in the first direction D1. Here, the fifth bonding wires 160 may have a loop-shaped portion that protrude above relative to the top surface of the fourth semiconductor chip 600.

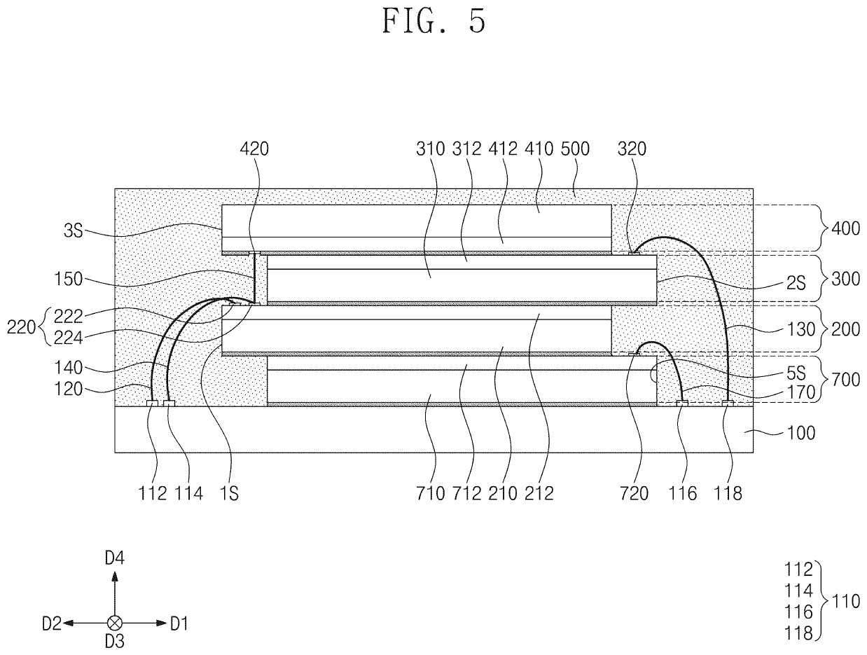

FIG. 5 is a sectional view illustrating a semiconductor package according to an example embodiment of the inventive concepts. Referring to FIG. 5, the substrate 100 may be provided. The substrate 100 may have the same or substantially similar features as the substrate 100 in the example embodiment of FIG. 4. For example, the substrate pads 110 may be arranged in four columns extended in the third direction D3. The substrate pads 110 of the four columns may be referred to as first column substrate pads 112, second column substrate pads 114, third column substrate pads 116, and fourth column substrate pads 118. The first column substrate pads 112 may mean a group of the substrate pads 110 included in the column that is farthest from the center of the substrate 100 in the second direction D2, and the fourth column substrate pads 118 may mean a group of the substrate pads 110 included in the column that is farthest from the center of the substrate 100 in the first direction D1.

A fifth semiconductor chip 700 may be provided on the substrate 100. The fifth semiconductor chip 700 may include a fifth semiconductor substrate 710 and a fifth interconnection layer 712 on the fifth semiconductor substrate 710. The fifth semiconductor chip 700 may be provided in a face-up manner. For example, a top surface of the fifth semiconductor chip 700 may be an active surface of the fifth semiconductor chip 700, on which interconnection patterns are provided. The fifth semiconductor chip 700 may be provided between the substrate 100 and the first semiconductor chip 200. The fifth semiconductor chip 700 may be disposed on the center portion of the substrate 100. When viewed in a plan view, the fifth semiconductor chip 700 may be horizontally spaced apart from the substrate pads 110 disposed on the outer edge portion of the substrate 100. The fifth semiconductor chip 700 may be disposed between the second column substrate pads 114 and the third column substrate pads 116, when viewed in a plan view.

The fifth semiconductor chip 700 may include the fifth semiconductor substrate 710. The fifth semiconductor substrate 710 may include a semiconductor material. The fifth semiconductor substrate 710 may be a silicon substrate, a silicon-on-insulator (SOI) substrate, a germanium (Ge) substrate, a germanium-on-insulator (GOI) substrate, a silicon-germanium (SiGe) substrate, a group III-V semiconductor substrate, or a substrate including an epitaxial film formed by a selective epitaxial growth (SEG) process. The fifth semiconductor substrate 710 may be formed of or include at least one of silicon (Si), germanium (Ge), silicon-germanium (SiGe), gallium arsenic (GaAs), indium gallium arsenic (InGaAs), or aluminum gallium arsenic (AlGaAs). Although not shown, integrated devices or integrated circuits may be formed on an active surface of the fifth semiconductor substrate 710. A top surface of the fifth semiconductor substrate 710 may be the active surface of the fifth semiconductor substrate 710. The integrated circuit may include a logic circuit or a memory circuit. In other words, the fifth semiconductor chip 700 may be a logic chip or memory chip. However, the inventive concepts is not limited to this example, and in an example embodiment, the fifth semiconductor chip 700 may be a logic chip, a memory chip, or a semiconductor chip including various integrated devices.

The fifth interconnection layer 712 may be disposed on the active surface of the fifth semiconductor substrate 710. For example, although not shown, the fifth interconnection layer 712 may include a fifth insulating pattern and a fifth interconnection pattern provided on the active surface of the fifth semiconductor substrate 710. The fifth insulating pattern may include an insulating material. For example, the fifth insulating pattern may be formed of or include at least one of silicon oxide (SiO), silicon nitride (SiN), silicon oxynitride (SiON), silicon carbonitride (SiCN), insulating polymers, or photosensitive insulating materials (PID). The fifth interconnection pattern may be provided in the fifth insulating pattern. The fifth interconnection pattern may be electrically connected to the integrated device or the integrated circuit. The fifth interconnection pattern may be formed of or include at least one of conductive materials (e.g., copper (Cu) or aluminum (Al)).

The fifth semiconductor chip 700 may include fifth pads 720, which are provided on the active surface of the fifth semiconductor substrate 710. The fifth pads 720 may be provided on a region of the top surface of the fifth semiconductor chip 700, which is adjacent to a fifth side surface 5S of the fifth semiconductor chip 700. In the present specification, the fifth side surface 5S of the fifth semiconductor chip 700 may be a side surface of the fifth semiconductor chip 700 that is parallel to the third direction D3 and is spaced apart from a center of the fifth semiconductor chip 700 in the first direction D1. The fifth pads 720 may be disposed to be spaced apart from each other in the third direction D3. The fifth pads 720 may be provided as elements protruding relative to the top surface of the fifth semiconductor chip 700. However, the inventive concepts is not limited to this example, and in an example embodiment, the fifth pads 720 may be coplanar with the top surface of the fifth semiconductor chip 700 and may be exposed to the outside of the fifth semiconductor chip 700 near the top surface of the fifth semiconductor chip 700. At least one of the fifth pads 720 may be electrically connected to the integrated device or the integrated circuits.

The fifth pads 720 may be attached to the substrate 100 using a fifth adhesive layer. The fifth adhesive layer may include a conductive film (e.g., a die attach film (DAF)) or a non-conductive film (NCF). The fifth adhesive layer may cover a bottom surface of the fifth semiconductor chip 700 and may fill a space between the substrate 100 and the fifth semiconductor chip 700.

The fifth semiconductor chip 700 may be mounted on the substrate 100. For example, the fifth semiconductor chip 700 may be electrically connected to the substrate 100 through sixth bonding wires 170. The sixth bonding wires 170 may be extended from top surfaces of the third column substrate pads 116 to top surfaces of the fifth pads 720 provided on the top surface of the fifth semiconductor chip 700. The sixth bonding wires 170 may be formed of or include at least one of metallic materials (e.g., gold (Au)). The substrate 100 may be electrically connected to the integrated circuits of the fifth semiconductor chip 700 through the sixth bonding wires 170, the fifth pads 720.

The first to third semiconductor chips 200, 300, and 400 may be stacked on the top surface of the fifth semiconductor chip 700. The first to third semiconductor chips 200, 300, and 400 may have the same or substantially similar features as those in the example embodiment of FIG. 1. The first semiconductor chip 200 may be stacked on the fifth semiconductor chip 700 and may be offset from the fifth semiconductor chip 700 in the second direction D2. At least a portion of the first semiconductor chip 200 may vertically overlap at least a portion of the fifth semiconductor chip 700. A portion of the first semiconductor chip 200 may protrude relative to a side surface of the fifth semiconductor chip 700, which is opposite to the fifth side surface 5S. For example, the first side surface 1S of the first semiconductor chip 200 may protrude relative to the side surface of the fifth semiconductor chip 700 that is opposite to the fifth side surface 5S. When viewed in a plan view, the fifth pads 720 may be horizontally spaced apart from the first semiconductor chip 200. The fifth pads 720 may be disposed on the top surface of the fifth semiconductor chip 700 and may be spaced apart from the first semiconductor chip 200 in the first direction D1.

Each of the first to third semiconductor chips 200, 300, and 400 may be attached to the top surface of the semiconductor chip thereunder using the first to third adhesive layers that are provided on the bottom surfaces of the first to third semiconductor chips 200, 300, and 400. The substrate 100 and the first to third semiconductor chips 200, 300, and 400 may be electrically connected to each other through the first to fourth bonding wires 120, 130, 140, and 150. For example, the first bonding wires 120 may be extended from the top surfaces of the first column substrate pads 112 to the top surfaces of the first connection pads 222 to electrically connect the substrate 100 to the first semiconductor chip 200. The second bonding wires 130 may be extended from the top surfaces of the fourth column substrate pads 118 to the top surfaces of the second pads 320 to electrically connect the substrate 100 to the second semiconductor chip 300.

The mold layer 500 may be provided on the top surface of the substrate 100 to cover the first to third semiconductor chips 200, 300, and 400 and the fifth semiconductor chip 700. The mold layer 500 may fill a space between the substrate 100 and the first semiconductor chip 200, between the first semiconductor chip 200 and the third semiconductor chip 400, and between the fifth semiconductor chip 700 and the second semiconductor chip 300. The mold layer 500 may enclose the first to fourth bonding wires 120, 130, 140, and 150 and the sixth bonding wires 170.

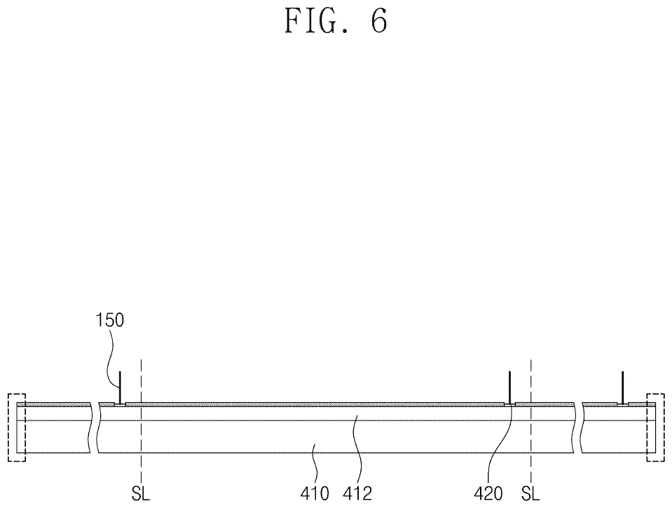

FIGS. 6 to 10 are sectional views illustrating a method of fabricating a semiconductor package, according to some example embodiments of the inventive concepts.

Referring to FIG. 6, the third semiconductor substrate 410 may be provided. The third interconnection layer 412 and the third pads 420 may be formed on the active surface of the third semiconductor substrate 410. A third adhesive layer may be formed to cover the third interconnection layer 412. The third adhesive layer may cover the third pads 420. The third adhesive layer may include a non-conductive film (NCF) or a conductive film (e.g., a die attach film (DAF)). By irradiating the third adhesive layer with a laser beam, the third adhesive layer may be patterned to form penetration holes on the third pads 420. However, the inventive concepts is not limited to this example, and in an example embodiment, the penetration holes may be formed through an exposure process. For example, a mask pattern may be formed on a top surface of the third adhesive layer. The mask pattern may have patterns exposing the top surface of the third adhesive layer. For example, the patterns may define regions where the penetration holes will be formed. The penetration holes may be formed by etching the third adhesive layer, and then, the mask pattern may be removed. Each of the penetration holes may be formed on a corresponding one of the third pads 420. The penetration holes may partially expose top surfaces of the third pads 420. A bottom of each of the penetration holes may be coplanar with the top surface of a corresponding one of the third pads 420.

The fourth bonding wires 150, which are extended from the third pads 420, may be formed. Although not shown, the fourth bonding wire 150 may include a wire ball, which is formed in a connection region where the fourth bonding wire 150 and the third pad 420 are connected to each other. Hereinafter, for convenience in description, a process of forming the fourth bonding wires 150 on the third pads 420 will be described with reference to one of the fourth bonding wires 150. A capillary may be configured to melt a wire, which is inserted therein, and to form a wire ball at a bottom end thereof. The wire ball may be used as a bump for a physical coupling between an end of the wire and a pad. The capillary may be moved to a region on the third pad 420. By performing a bonding process under a specific pressure, the wire ball may be attached to the third pad 420. Next, the capillary may be moved from the wire ball in a direction perpendicular to the active surface of the third semiconductor substrate 410 to form a wire. The fourth bonding wire 150 may be formed such that an end portion thereof is bonded to the third pad 420. The fourth bonding wires 150 may be formed by repeating this process for each of the third pads 420. Here, the fourth bonding wires 150, which are formed by the capillary, may have a linear shape, as in the example embodiment of FIG. 1. For example, the fourth bonding wires 150 may be formed in a direction perpendicular to top surfaces of the third pads 420. A length of each of the fourth bonding wires 150 may be equal to or larger than the distance between the third semiconductor chip 400 and the substrate 100 shown in FIG. 1. The fourth bonding wires 150 may include a metallic material (e.g., gold (Au)). Next, a sawing process may be performed along a sawing line SL to form a plurality of third semiconductor chips 400 connected to the fourth bonding wires 150.

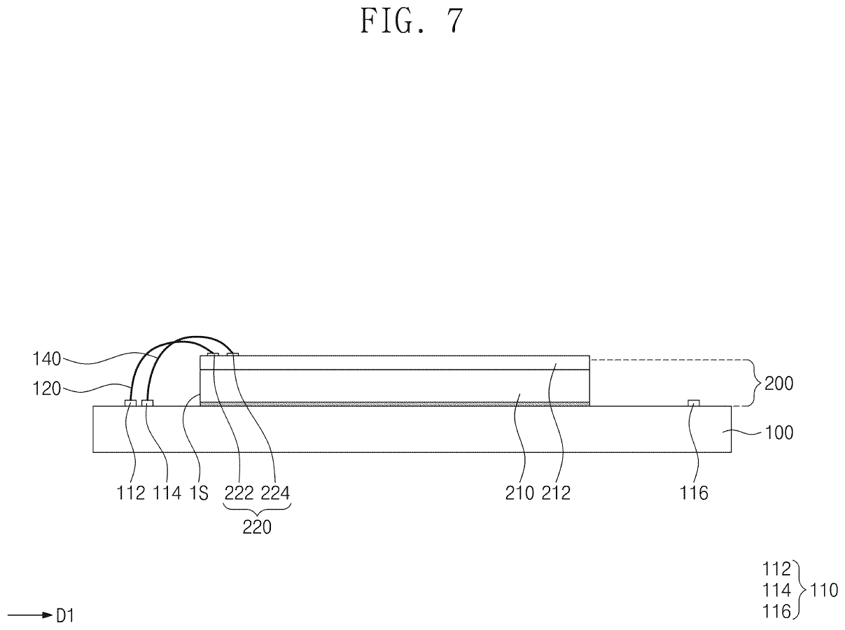

Referring to FIG. 7, the substrate 100 may be provided. The substrate 100 may have the same or substantially similar features as the substrate 100 described with reference to FIG. 1. The substrate 100 may be a printed circuit board (PCB) or a semiconductor substrate. The substrate 100 may include the substrate pads 110 disposed on the outer edge portion of the top surface of the substrate 100. The substrate pads 110 may include the first to third column substrate pads 112, 114, and 116.

The first semiconductor chip 200 may be provided on the center portion of the substrate 100. The first semiconductor chip 200 may have the same or substantially similar features as the first semiconductor chip 200 described with reference to FIG. 1. A first adhesive layer may cover the bottom surface of the first semiconductor chip 200. The first adhesive layer may include a non-conductive film (NCF) or a conductive film (e.g., a die attach film (DAF)). For example, the first semiconductor chip 200 with the first adhesive layer may be placed on the center portion of the top surface of the substrate 100 to be horizontally spaced apart from the second column substrate pads 114 and the third column substrate pads 116.

The first semiconductor chip 200 may be mounted on the substrate 100. The first bonding wires 120 may be formed between a top surface of the first semiconductor chip 200 and the substrate 100. The first bonding wires 120 may be extended from the first column substrate pads 112 to the first connection pads 222 of the first semiconductor chip 200. For example, the capillary provided with a wire ball may be moved to one of the first column substrate pads 112 of the substrate 100 to perform a bonding process. Thereafter, a loop process may be performed to move the capillary, which ejects a wire, to a region on one of the first connection pads 222. The capillary may be configured to form a wire ball at an opposite end of the wire, and thus, the opposite end of the wire may be connected to the one of the first connection pads 222. As a result of the bonding and loop processes, the first bonding wires 120 may connect the first column substrate pads 112 to the first connection pads 222, respectively.

The third bonding wires 140 may be formed between the top surface of the first semiconductor chip 200 and the substrate 100. The bonding and loop processes may be performed on the second column substrate pads 114 and the second connection pads 224. Thus, the third bonding wires 140 may connect the substrate 100 to the first semiconductor chip 200. The first and third bonding wires 120 and 140 may be formed of or include a metallic material (e.g., gold (Au)).

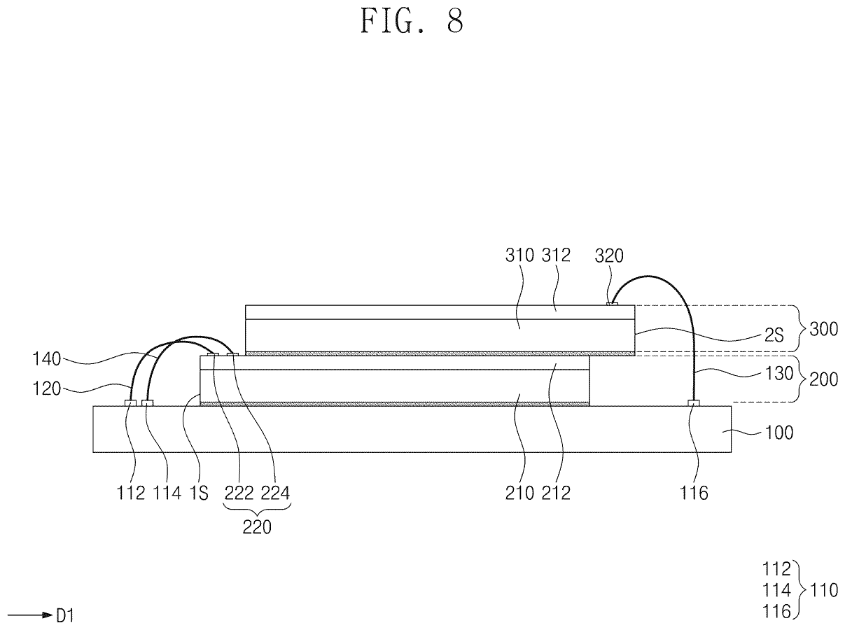

Referring to FIG. 8, the second semiconductor chip 300 may be stacked on the top surface of the first semiconductor chip 200 and may be offset from the top surface of the first semiconductor chip 200 in the first direction D1. The second semiconductor chip 300 may be fastened to the first semiconductor chip 200 by a second adhesive layer. The second adhesive layer may be attached to the bottom surface of the second semiconductor chip 300, and then, the second semiconductor chip 300 with the second adhesive layer may be attached or fastened to the top surface of the first semiconductor chip 200. The second adhesive layer may include a non-conductive film (NCF) or a conductive film (e.g., a die attach film (DAF)). The second adhesive layer may include the same material as the first adhesive layer.

The second bonding wires 130 may be formed between the top surface of the second semiconductor chip 300 and the substrate 100. The second bonding wires 130 may be extended from the third column substrate pads 116 to the second pads 320 on the top surface of the second semiconductor chip 300. For example, the capillary may be moved to one of the third column substrate pads 116 of the substrate 100 to perform the bonding process. Thereafter, the loop process may be performed to move the capillary, which ejects a wire, to a region on one of the second pads 320. The capillary may be configured to form a wire ball at an opposite end of the wire, and thus, the opposite end of the wire may be connected to the one of the second pads 320. As a result of the bonding and loop processes, the second bonding wires 130 may connect the third column substrate pads 116 to the second pads 320, respectively. The second bonding wires 130 may include a metallic material (e.g., gold (Au)). The second pads 320 of the second semiconductor chip 300 may be connected to the substrate pads 110 on the substrate 100 through the second bonding wires 130. That is, the second semiconductor chip 300 may be mounted on the substrate 100 in a wire bonding manner.

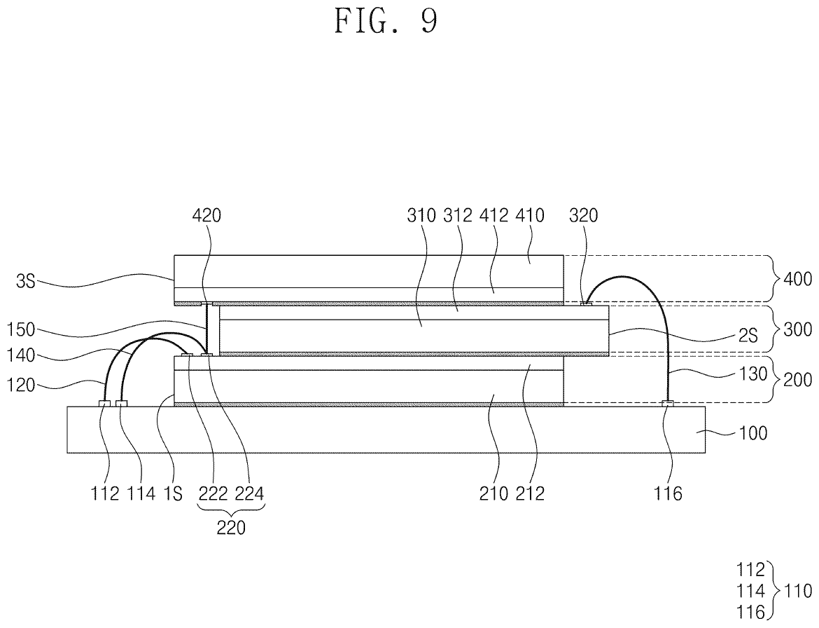

Referring to FIG. 9, the third semiconductor chip 400 may be provided on the structure of FIG. 8. The structure of FIG. 6 may be inverted on the structure of FIG. 8. For example, the third semiconductor chip 400 may be provided on the top surface of the second semiconductor chip 300 in such a way that the third pads 420 face the top surface of the substrate 100. The third semiconductor chip 400 may be stacked on the second semiconductor chip 300 and may be offset from the second semiconductor chip 300 in the second direction D2. At least a portion of the third pads 420 may vertically overlap at least a portion of the second connection pads 224. Opposite ends of the fourth bonding wires 150, which are not coupled to the third pads 420, may be in contact with the second connection pads 224. Because the second column substrate pads 114 and the second connection pads 224 are connected to each other through the third bonding wires 140 and the second connection pads 224 are connected to the fourth bonding wires 150 connected to the third pads 420, the substrate 100 may be electrically connected to the third semiconductor chip 400. In other words, the third pads 420 of the third semiconductor chip 400 may be connected to the substrate pads 110 on the substrate 100 through the third and fourth bonding wires 140 and 150. That is, the third semiconductor chip 400 may be mounted on the substrate 100 in a wire bonding manner. Although not shown, each of the fourth bonding wires 150 may have a wire ball, which is formed at one of opposite ends thereof. After the formation of the fourth bonding wires 150 extended from the third pads 420, the opposite ends of the fourth bonding wires 150 may be in contact with the second connection pads 224. Thus, only portions of the fourth bonding wires 150, which are connected to the third pads 420, may be provided to have wire balls. Unlike the illustrated structure, the fourth bonding wires 150 may have a curved shape. For example, the third semiconductor chip 400 may be moved toward the first semiconductor chip 200 in a downward direction to bring the fourth bonding wires 150 in contact with the second connection pads 224, and during this process, the fourth bonding wires 150 may be bent by a pressure.

Referring back to FIG. 1, the mold layer 500 may be formed on the substrate 100. The mold layer 500 may cover the first to third semiconductor chips 200, 300, and 400. Alternatively, the third semiconductor chip 400 may be formed such that the top surface thereof is exposed to the outside of the mold layer 500 near the top surface of the mold layer 500. The mold layer 500 may enclose the first to fourth bonding wires 120, 130, 140, and 150. For example, an insulating material may be coated to encapsulate the first to third semiconductor chips 200, 300, and 400, and then, the insulating material may be cured to form the mold layer 500. Thus, the semiconductor package may be formed to have the structure of FIG. 1.

FIGS. 6 to 9 illustrate an example, in which the third semiconductor chip 400 formed by the process of FIG. 6 is mounted on the structure of FIG. 8, but the inventive concepts is not limited to this example. In an example embodiment, the second semiconductor chip 300 may be formed using the process of FIG. 6. For example, the second interconnection layer 312 and the second pads 320 may be formed on the second semiconductor substrate 310. A second adhesive layer may be formed to cover the second interconnection layer 312, and here, the second pads 320 may be formed to have a top surface exposed to the outside of the second adhesive layer. The second bonding wires 130, which are extended from the second pads 320, may be formed to have a linear shape. The second bonding wires 130 each may have a length that is equal to or larger than a distance between the second semiconductor chip 300 and the substrate 100 shown in FIG. 2. Thereafter, a sawing process may be performed along the sawing line SL to form a plurality of second semiconductor chips 300 connected to the second bonding wires 130.

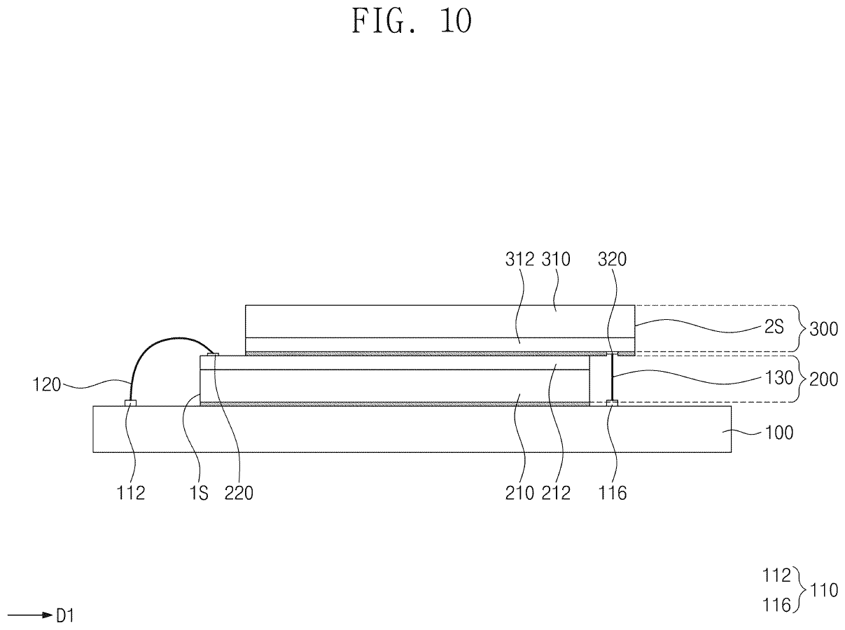

Referring to FIG. 10, the second semiconductor chips 300 may be provided on the substrate 100. The substrate 100 may have the same or substantially similar features as the substrate 100 described with reference to FIG. 2. The substrate 100 may be a printed circuit board (PCB) or a semiconductor substrate. The substrate 100 may include the substrate pads 110 disposed on an outer edge portion of the top surface of the substrate 100. The substrate pads 110 may include the first and third column substrate pads 112 and 116. The first semiconductor chip 200 may be provided on the center portion of the substrate 100. The first semiconductor chip 200 may be the same as or substantially similar to the first semiconductor chip 200 described with reference to FIG. 1. The first semiconductor chip 200 attached with the first adhesive layer may be placed on the center portion of the top surface of the substrate 100 to be horizontally spaced apart from the first and third column substrate pads 112 and 116. The first semiconductor chip 200 may be mounted on the substrate 100 in a wire bonding manner. By performing the bonding and loop processes, the first bonding wires 120 may be formed between the top surface of the first semiconductor chip 200 and the substrate 100 to connect the first column substrate pads 112 to the first connection pads 222 (e.g., the first pads 220), respectively.

The second semiconductor chip 300 may be stacked on the top surface of the first semiconductor chip 200 and may be offset from the top surface of the first semiconductor chip 200 in the first direction D1. For example, the second semiconductor chip 300 may be provided on the top surface of the first semiconductor chip 200 in such a way that the second pads 320 face the top surface of the substrate 100. At least a portion of the second pads 320 may vertically overlap at least a portion of the third column substrate pads 116. Opposite ends of the second bonding wires 130, which are not coupled to the second pads 320, may be in contact with the third column substrate pads 116. The second pads 320 of the second semiconductor chip 300 may be connected to the substrate pads 110 on the substrate 100 through the second bonding wires 130. After the formation of the second bonding wires 130 extended from the second pads 320, the opposite ends of the second bonding wires 130 may be in contact with the third column substrate pads 116. Thus, one of opposite ends of the second bonding wire 130 may be provided to have a wire ball. For example, only portions of the second bonding wires 130, which are connected to the second pads 320, may be provided to have wire balls. Unlike the illustrated structure, the second bonding wires 130 may have a curved shape. For example, the second semiconductor chip 300 may be moved toward the first semiconductor chip 200 in a downward direction to bring the second bonding wires 130 in contact with the third column substrate pads 116, and during this process, the second bonding wires 130 may be bent by a pressure.

Referring back to FIG. 2, the mold layer 500 may be formed on the substrate 100. The mold layer 500 may cover the first and second semiconductor chips 200 and 300. The mold layer 500 may enclose the first and second bonding wires 120 and 130. For example, an insulating material may be coated to encapsulate the first and second semiconductor chips 200 and 300, and then, the insulating material may be cured to form the mold layer 500. Thus, the semiconductor package may have the structure of FIG. 2.

In a semiconductor package according to an example embodiment of the inventive concepts, a vertical wire may connect the uppermost one of semiconductor chips, which are stacked on a substrate and are offset from each other, to the substrate. Because the wire does not protrude relative to a side surface of the uppermost semiconductor chip, it may be possible to reduce a size of the semiconductor package.

In a semiconductor package according to an example embodiment of the inventive concepts, a vertical wire may connect the uppermost one of semiconductor chips, which are stacked on a substrate and are offset from each other, to the substrate. Thus, a protruding portion of the uppermost semiconductor chip may be supported by the vertical wire, and this may make it possible to improve the structural stability of the semiconductor package.

While some example embodiments of the inventive concepts have been particularly shown and described, it will be understood by one of ordinary skill in the art that variations in form and detail may be made therein without departing from the spirit and scope of the attached claims.

What is claimed is:

1. A semiconductor package, comprising:
a substrate;
a first semiconductor chip on the substrate;
a second semiconductor chip stacked on the first semiconductor chip, the second semiconductor chip being offset from the first semiconductor chip in a first direction;
a third semiconductor chip stacked on the second semiconductor chip, the third semiconductor chip being offset from the second semiconductor chip in a second direction, the second direction being opposite to the first direction;
a first bonding wire connecting the substrate to the first semiconductor chip; and
a second bonding wire connecting the first semiconductor chip to the third semiconductor chip,
wherein the first semiconductor chip comprises a first chip pad, the first chip pad being on a top surface of the first semiconductor chip, the first chip pad being spaced apart from the second semiconductor chip in the second direction,
the third semiconductor chip comprises a second chip pad, the second chip pad being on a bottom surface of the third semiconductor chip, the second chip pad being spaced apart from the second semiconductor chip in the second direction,
the second chip pad being above the first chip pad,
the first bonding wire is extended from a top surface of the substrate to a top surface of the first chip pad, and
the second bonding wire is spaced apart from the second semiconductor chip in the second direction and is extended from the top surface of the first chip pad to a bottom surface of the second chip pad.

2. The semiconductor package of claim 1, wherein the second bonding wire is extended in a direction perpendicular to the top surface of the substrate.

3. The semiconductor package of claim 1, wherein
the first semiconductor chip is attached to the top surface of the substrate using a first adhesive layer covering a bottom surface of the first semiconductor chip,
the second semiconductor chip is attached to the top surface of the first semiconductor chip using a second adhesive layer covering a bottom surface of the second semiconductor chip, and
the third semiconductor chip is attached to a top surface of the second semiconductor chip using a third adhesive layer covering the bottom surface of the third semiconductor chip.

4. The semiconductor package of claim 3, wherein
the third adhesive layer comprises a penetration hole,
the penetration hole vertically penetrates the third adhesive layer, and
the penetration hole exposes the bottom surface of the second chip pad.

5. The semiconductor package of claim 4, wherein the first to third adhesive layers comprise a die attach film (DAF) or a non-conductive film (NCF).

6. The semiconductor package of claim 1, further comprising:
a third bonding wire electrically connecting the substrate to the second semiconductor chip,
wherein the second semiconductor chip comprises a third chip pad, the third chip pad being on a top surface of the second semiconductor chip and spaced apart from the third semiconductor chip in the first direction, and
the third bonding wire is extended from the top surface of the substrate to a top surface of the third chip pad.

7. The semiconductor package of claim 1, further comprising:
a fourth bonding wire electrically connecting the substrate to the second semiconductor chip,
wherein the second semiconductor chip comprises a fourth chip pad, the fourth chip pad being on a bottom surface of the second semiconductor chip and spaced apart from the first semiconductor chip in the first direction, and
the fourth bonding wire is extended from the top surface of the substrate in a direction perpendicular to the substrate and is coupled to a bottom surface of the fourth chip pad.

8. The semiconductor package of claim 1, further comprising:
a fifth bonding wire electrically connecting the substrate to the first semiconductor chip, wherein
the first semiconductor chip comprises
an integrated circuit adjacent to the top surface of the first semiconductor chip, and
a fifth chip pad being on the top surface of the first semiconductor chip and spaced apart from the second semiconductor chip in the second direction,
the fifth chip pad is horizontally spaced apart from the first chip pad, when viewed in a plan view,
the fifth bonding wire is extended from the top surface of the substrate and is coupled to a top surface of the fifth chip pad,
the fifth chip pad is electrically connected to the integrated circuit, and
the first chip pad is electrically disconnected from the integrated circuit.

9. The semiconductor package of claim 1, further comprising:
a plurality of semiconductor chips stacked between the second semiconductor chip and the third semiconductor chip,
wherein the semiconductor chips are stacked on the second semiconductor chip to form a stepwise structure in the first direction.

10. A semiconductor package, comprising:
a substrate comprising substrate pads on a top surface of the substrate;
an outer connection terminal on a bottom surface of the substrate;
a first semiconductor chip on the substrate, the first semiconductor chip comprising first chip pads, the first chip pads being on a region of a top surface of the first semiconductor chip that is adjacent to a side surface of the first semiconductor chip;
a second semiconductor chip stacked on the first semiconductor chip, the second semiconductor chip being offset from the first semiconductor chip in a first direction and horizontally spaced apart from the first chip pads, when viewed in a plan view;
a third semiconductor chip stacked on the second semiconductor chip, the third semiconductor chip being offset from the second semiconductor chip in a second direction, the second direction being opposite to the first direction, the third semiconductor chip comprising second chip pads, the second chip pads being on a bottom surface of the third semiconductor chip and spaced apart from the second semiconductor chip in the second direction;
first bonding wires electrically connecting the substrate to the first semiconductor chip;
second bonding wires electrically connecting the substrate to the second semiconductor chip;
third bonding wires electrically connecting the substrate to the third semiconductor chip; and
a mold layer on the substrate, the mold layer covering top and side surfaces of the first to third semiconductor chips, the mold layer enclosing the first to third bonding wires,
wherein the third bonding wires comprise first sub-wires and second sub-wires, the first sub-wires extending from top surfaces of the substrate pads to top surfaces of the first chip pads in a curved shape, the second sub-wires extending from the top surfaces of the first chip pads to bottom surfaces of the second chip pads in a linear shape.

11. The semiconductor package of claim 10, further comprising:
an adhesive layer covering the bottom surface of the third semiconductor chip,
wherein the adhesive layer comprises penetration holes, the penetration holes vertically penetrating the adhesive layer and exposing the bottom surfaces of the second chip pads.

12. The semiconductor package of claim 10, wherein
the substrate pads comprise first substrate pads and second substrate pads,
the first and second substrate pads are arranged in respective columns, each of the first substrate pads and the second substrate pads extending in a direction parallel to the side surface of the first semiconductor chip, and
when viewed in a plan view, the first semiconductor chip is between the first substrate pads and the second substrate pads.

13. The semiconductor package of claim 12, wherein
the first semiconductor chip comprises
an integrated circuit in the first semiconductor chip and
third chip pads connected to the integrated circuit,
the third chip pads are on the region of the first semiconductor chip adjacent to the side surface of the first semiconductor chip,
the first and third chip pads are arranged in respective columns, each of the first chip pads and the third chip pads extending in the direction parallel to the side surface,
the first chip pads and the third chip pads are spaced apart from each other in the second direction,
the first bonding wires are extended from top surfaces of the first substrate pads and are coupled to top surfaces of the third chip pads, and
the first chip pads are electrically disconnected from the integrated circuit.

14. The semiconductor package of claim 13, wherein
the second semiconductor chip comprises fourth chip pads, the fourth chip pads being on a bottom surface of the second semiconductor chip and spaced apart from the first semiconductor chip in the first direction, and
the second bonding wires are spaced apart from the first semiconductor chip in the first direction and are extended from top surfaces of the second substrate pads to bottom surfaces of the fourth chip pads.

15. The semiconductor package of claim 10, further comprising:
a fourth semiconductor chip between the second semiconductor chip and the third semiconductor chip,
wherein the fourth semiconductor chip is stacked on the second semiconductor chip and is offset from the second semiconductor chip in the first direction.

16. A semiconductor package, comprising:
a substrate;
a first semiconductor chip and a second semiconductor chip stacked on the substrate to have a stepwise structure in a first direction, the first semiconductor chip comprising first chip pads, the first chip pads being on a top surface of the first semiconductor chip and spaced apart from the second semiconductor chip in a second direction opposite to the first direction;
a third semiconductor chip stacked on the second semiconductor chip, the third semiconductor chip being offset from the second semiconductor chip in the second direction, the third semiconductor chip comprising second chip pads, the second chip pads being on a bottom surface of the third semiconductor chip and spaced apart from the second semiconductor chip in the second direction;
first bonding wires extended from a top surface of the substrate to top surfaces of the first chip pads; and
second bonding wires extended from the top surfaces of the first chip pads to bottom surfaces of the second chip pads,
wherein the third semiconductor chip is attached to a top surface of the second semiconductor chip using an adhesive layer covering the bottom surface of the third semiconductor chip,
the adhesive layer exposes the bottom surfaces of the second chip pads, and
each of the second chip pads is above a corresponding one of the first chip pads.

17. The semiconductor package of claim 16, wherein the adhesive layer comprises penetration holes, the penetration holes vertically penetrating the adhesive layer and exposing the bottom surfaces of the second chip pads.

18. The semiconductor package of claim 16, wherein the adhesive layer comprises a die attach film (DAF) or a non-conductive film (NCF).

19. The semiconductor package of claim 16, wherein the second bonding wires overlap the third semiconductor chip, when viewed in a plan view.

20. The semiconductor package of claim 16, further comprising:
a mold layer on the top surface of the substrate, the mold layer covering the first to third semiconductor chips,
wherein the mold layer fills a space between the first chip pads and the second chip pads and encloses the second bonding wires.
